(19) United States
(12) Patent Application Publication
(10) Pub. No.: US 2017/0124222 A1
(43) Pub. Date: May 4, 2017

(54) ITEM MATCH SEARCHING IN A LIST

(71) Applicant: BULL SAS, Les Clayes sous Bois (FR)

(72) Inventor: Ghassan CHEHAIBAR, GUYANCOURT (FR)

(21) Appl. No.: 15/318,476

(22) PCT Filed: Jun. 4, 2015
(86) PCT No.: PCT/FR2015/051484

§ 371 Date: Dec. 13, 2016

(30) Foreign Application Priority Data
Jun. 13, 2014 (FR) 1455394

(51) Int. Cl. G06F 17/30; G06F 12/126; G11C 15/00

(52) U.S. Cl. CPC G06F 17/30982; G11C 15/00; G06F 12/126; G06F 2212/69

(57) ABSTRACT

A device for searching for element correspondence in a list, the device including: a plurality of content-addressable memory modules configured so as to be able to compare in parallel an input element with the content thereof, the list being represented by the concatenation of the valid content of the memories in an order defined by a list of priority, a module for the determination, in the list of priority, of the first module wherein the input element corresponds to an element stored in the module, and a module for reading the first element of the determined module corresponding to the input element,

The present invention concerns the field of information technology. More particularly, it concerns the implementation of searching for items in lists using hardware.

The implementation of network cards supporting the MPI interface (MPI standing for “Message Passing Interface”) requires the massive employment of item searching in lists.

This requires, for example, listing the messages expected by a node of a communication network with an indication as to its storage site and comparing all the incoming messages of the node with those of the list. Thus, when a message arrives, it may be conveyed to the storage site for processing.

Conventionally, each message has a tag which must be compared with the tag of the messages in the list. The tags of messages of the list may possibly be masked in order for the comparison of the tags to be made over a reduced number of bits.

When a message arrives, its tag is compared to that of the first item of the list, then the second, then the third and so forth, until a tag match is found.

In this case, the incoming message is conveyed to the storage site and the matching item of the list is deleted. The list is next updated.

The list of the expected messages is thus a dynamically modified list with items which may be removed, when a matching message arrives or which may be added when a new message is expected.

This type of search in a list may be software-implemented, with list traversals, but this type of implementation has a high consumption of computing resources.

Furthermore, as the incoming message has to be sequentially compared with all the items of the list, the processing time is proportional to the size of the list. In applications employing a very high number of processors, typically supercomputers, software implementation may slow the system too heavily.

Thus, hardware implementations may be preferred. It has in particular be proposed to conduct match searches in parallel, for example using search trees.

Parallel searches for matches are however complex since, in the context of MPI interfaces for example, only the first item matching the incoming message must be yielded. The concept of order of items of the list must be kept, even in parallel searches for matches.

There is thus a need to improve information technology hardware implementations for item match searching in lists.

The present invention lies within this context.

A first aspect of the invention concerns a device for item match searching in a list, the device comprising:

a plurality of content addressable memory modules that are configured to compare in parallel an entry item with their content, said list being represented by the concatenation of the valid content of said memories in an order defined by a priority list,

a module for determining, in said priority list, the first module for which the entry item matches an item stored in said module, and

a module for reading the first item of said determined module matching the entry item.

A device according to the first aspect enables item match searches to be carried out in a reduced number of clock cycles in a computer system.

For example, the match searching for an item in a list of 1024 items may be carried out in less than 10 cycles.

For example, this device is an ALPU (standing for “Associative List Processing Unit”).

According to some embodiments, the device further comprises:

a module for invalidating said first item, and

an updating module for updating an item counter associated with said determined memory, said item counter representing the number of valid items stored in said memory.

According to some embodiments, said updating module is furthermore configured to launch an update of said priority list when a module is empty, said update enabling said module to be placed at a lower priority level than that of the modules that are not empty.

For example, a priority index associated with said memories is updated.

For example, said update comprises a shift of said module and of the following modules in the list.

According to some embodiments, said priority list comprises a parameter for each module, indicating whether each module is empty or not.

For example, the modules are classified according to said parameter.

Still by way of example, the order of the modules in said priority list reflects an allocation order.

According to some embodiments, said match searching is made by association of a tag of said item with a tag of an item of said list.

For example, said modules are memory modules addressable by ternary content.

This type of module consumes less energy than registers (known as “flip-flops”) which are usually used.

To process a list of S×N items, the device can contain N content addressable memory modules, each module being able to contain S items.

For example, at least one processing module of the device is formed from log₂(N) stages of multiplexers (log₂ representing the logarithm to base 2), N being the number of content addressable memory modules.

For example a processing unit is a re-ordering module, a selection module or other module.

A second aspect of the invention concerns a method for item match searching in a list, the method comprising the following steps:

comparing in parallel an entry item with the content of a plurality of content addressable memory modules, said list being represented by the concatenation of the valid content of said memories in an order defined by a priority list,

determining, in said priority list, the first module for which the entry item matches an item stored in said module,

reading the first item of said determined module matching the entry item.

The method may furthermore comprise the following steps:

invalidating said first item, and

updating an item counter associated with said determined memory, said item counter representing the number of valid items stored in said memory.

The method may furthermore comprise a step of updating said priority list when a module is empty, said updating enabling said module to be placed at a lower priority level than that of the modules that are not empty.

For example, a priority index associated with said memories is updated.

For example, said updating comprises a shift of said module and of the following modules in the list.

For example, said priority list comprises a parameter for each module, indicating whether each module is empty or not.

According to some embodiments, the modules are classified according to said parameter.

For example, the order of the modules in said priority list reflects an allocation order.

According to some embodiments, said match searching is made by association of a tag of said item with a tag of an item of said list.

According to some embodiments, said modules are memory modules addressable by ternary content.

A third aspect of the invention concerns a computer program as well as a computer program product and a storage medium for such program and product, enabling the implementation of a method according to the second aspect of the invention.

Other features and advantages of the invention will appear on reading the present detailed description which follows, by way of non-limiting example, and the appended drawings among which:

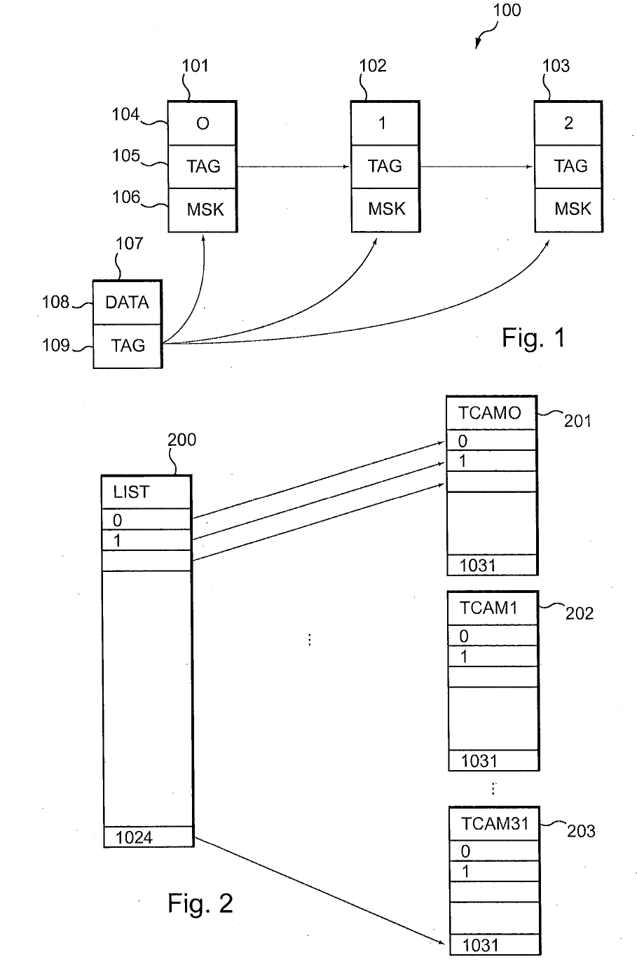

FIG. 1 illustrates a general objective of some embodiments of the invention,

FIG. 2 illustrates the storage of a list in content addressable memory modules according to some embodiments,

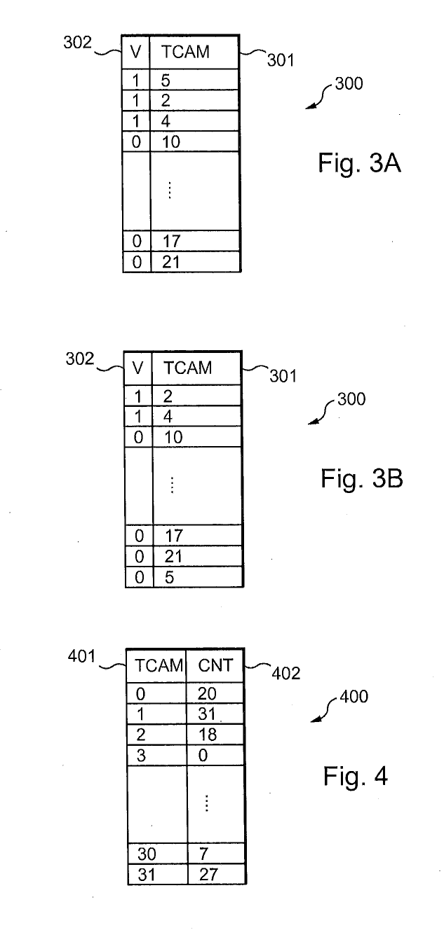

FIGS. 3A-3B illustrate the updating of a priority list according to some embodiments,

FIG. 4 illustrates a counting table according to some embodiments, and

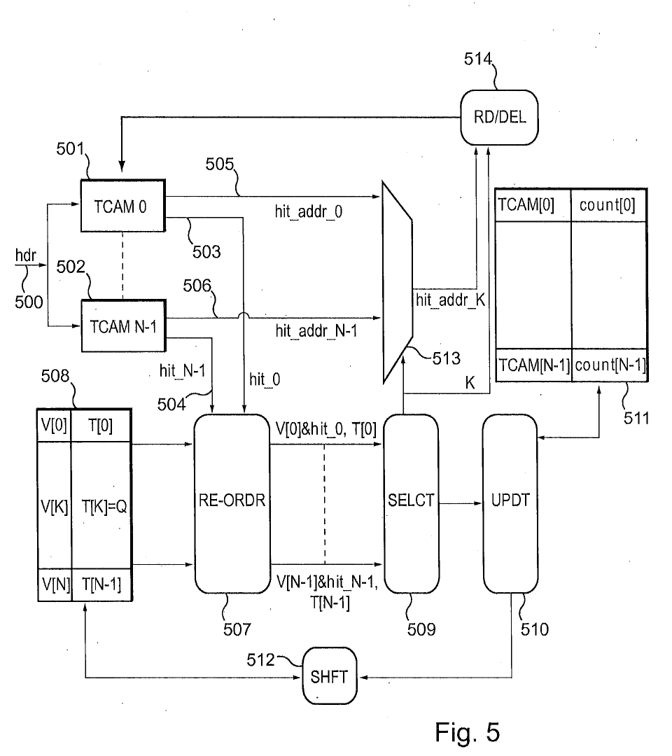

FIG. 5 illustrates a hardware implementation according to some embodiments.

According to a general objective illustrated by FIG. 1, a list 100 comprises a certain number of items 101, 102, 103, etc. ordered according to respective indexes “0”, “1”, “2”, etc. Each item of the list comprises, like the item 101, data 104 (“0”), a tag 105 (“TAG”) and possibly a mask 106 (“MSK”).

It is a matter of determining, in this list, the first item matching an entry item 107 comprising data 108 and a tag 109.

The matching is made by comparison between the tag of the entry item and that of the items of the list. To simplify the match searching, the comparison may be made with the masks of the items of the list. By comparing with the masks, the matching may be made over a smaller number of bits.

Rather than performing the match searching by traversing the list and making the comparisons one by one, it is provided to perform a parallel search.

For this, as illustrated in FIG. 2, the content addressable memory (CAM) modules are used. For example, these are Ternary Content Addressable Memory (TCAM) modules.

The list 200 (“LIST”) in which the search is to be made is stored in a set of modules 201 (“TCAM0”), 202 (“TCAM1”), . . . , 203 (“TCAM31”). For example, the list 200 comprises 1024 items distributed in 32 modules of 32 items. The modules are initially allocated an initial order, for example according to their index value. Thus, module 201 (“TCAM0”), of index “0” is allocated first, followed by 202 (“TCAM1”), of index “1” and so forth until module 203 (“TCAM31”) of index “31”. Another initial allocation order may be provided.

When an item of the list matches the entry item, it is removed from the list. Thus, the row of the module in which it is stored is invalidated. For example, a validity bit is updated to indicate that the row is “empty”. Again for example, the row is set to zero.

When all the rows of a module have been invalidated, the module becomes available again to store new items therein.

The concatenation of the valid rows of the modules placed in their order of allocation enables the list to be reconstituted in its current state.

In order to process a list of N×S items, N TCAMs are for example used, each able to contain S entries.

In order to manage the dynamic allocation of the modules, a priority list (not shown) identifies the modules and enables them to be put in order to enable the initial list to be reconstituted correctly.

FIG. 3A illustrates a priority list 300. A first column 301 comprises the index of the modules, in their order of priority. A second column 302 comprises a validity parameter (V) indicating whether the module has been allocated (V=1), that is to say that at least one row of the module stores an item of the list in which the match is searched for, or whether the module has not been allocated (V=0), that is to say that the module is free to store new items of the list therein.

To reconstitute the list in which the match is searched for, it suffices to concatenate, in the order given by the priority list, the valid rows of the allocated modules.

Thus, in the example of FIG. 3, to reconstitute the list, the valid rows of the module of index “5” must be concatenated, then that of index “2”, then that of index “4”. In the priority list, the allocated modules are placed before the non-allocated modules.

If for example, the module of index “5” (TCAM5) has just been emptied, that is to say that all its rows are invalidated (or erased) its validity parameter V becomes “0” and all the rows of the list 300 are shifted as illustrated by FIG. 3B. Thus, the module of index “2” becomes head of the list and the module of index “5” becomes a non-allocated module at the end of the priority list. The modules emptied in course of the match searching process may be in any position in the priority list, according to the matches found.

To determine whether a module is empty or not, a counting table 400, illustrated by FIG. 4, is updated according to the recordings and/or erasure (or invalidation) in the modules.

The table 400 comprises a column 401 listing the modules, for example according to their index, the module of index “0” (TCAM0) being listed first, followed by the module of index “1” (TCAM1) etc. A second column comprises a count value for each module, representing the number of valid rows in the module. Thus, for example, the module of index “0” (TCAM0) comprises 20 value rows, that is to say that 20 items of the list in which the match is searched for are stored in that module. The module of index “1” (TCAM1) comprises 31 valid rows. The module of index “3” (TCAM3) comprises 0 valid rows, that is to say that it is empty and thus available for allocation.

Each time a new item is integrated into the list, the counter of a module is incremented. Each time a match is found between an incoming item and an item of the list, that item of the list is deleted and the counter of the module in which it is stored is decremented.

The match searching between an entry item and the items of a list may be implemented in an associative list processing unit (ALPU), for example in a router employing an MPI interface.

In this type of interface, the messages arriving at a node of a communication network must be conveyed to be processed. Thus, a waiting list of messages to receive is established and the storage addresses for those messages are associated therein. When a message arrives at a node, it is compared with those of the waiting list (using a tag as mentioned above). When a match is found, the first matching message in the order of the waiting list is deleted therefrom. The message is then conveyed according to the associated address.

With reference to FIG. 5, a hardware implementation for match searching according to embodiments is described. This implementation may for example be made in the form of an ASIC (acronym for “Application-Specific Integrated Circuit”).

A tag 500 (“hdr”) of an item is provided in parallel to a series of content addressable memory modules. In this example, these are N ternary modules (TCAM modules) 501, . . . , 502, named “TCAM 0”, “TCAM N-1” (for example N=32). This tag is thus compared with the tags (possibly masked) of the data stored in the modules. It is to be recalled that the items stored in the modules are those of the list in which the match with the item of the tag 500 is searched for.

Each module provides as output a match bit 503, . . . , 504 (named “hit_0”, “hit_N-1”) of which the value is “1” if a match has been found and “0” if no match has been found in the module. Each module also provides a word mot 505, . . . , 506 (named “hit_addr_0”, . . . , “hit_addr_N-1”) representing the address of the first item in the module at which the match has been found.

The match bits provided by the modules thus form a result vector which is given as input to a re-ordering module 507. It is to be recalled that a match may be found in several modules, but it is desired to keep only the first.

The order in which the match bits are classified in the result vector is fixed whereas the allocation of the bits is dynamic. Thus, the module 507d gives as output, a list of pairs (V[K]&hit_[K], T[K]) where T[K] and V[K] come from a priority list such as described earlier above with reference to FIG. 3A of a module 508 for priority list management. In this priority list, T[K]=Q if the TCAM module (TCAMQ) of index Q has priority K in the list.

This ordered list of pairs enables a selection module 509 to select the first TCAM module of the list verifying V[K]=hit_K=1, that is to say the TCAM module of highest priority, that is valid (V[K]=1) and in which a match has been found (hit_K=1).

The modules 507 and 509 may for example be produced by means of stages of multiplexers, log₂(N+1) stages for module 507 and log₂(N) stages for module 509 (log₂ representing the logarithm to base 2). This is a measurement able to be generalized to other processing elements of the system. These elements may be produced by means of stages of multiplexers of which the number (of stages) may be of the order of log₂(N), N being the number of TCAMs used (log₂ representing the logarithm to base 2).

In an example, it is assumed that matches are found in the modules TCAM2 and TCAM5 (as illustrated by FIG. 3A). By taking the example of a result vector with positions from 0 to 31 from left to right (in general, in hardware architecture, the convention is the reverse, as represented in FIG. 5) this vector has as its first six bits 0, 0, 1, 0, 0, 1, 0, . . . . The re-ordering module produces the following pairs (taking the priorities indicated diagrammatically in FIG. 3): <1,5>, <1,2>, <0,4>, <0,10>, . . . (each pair is of the form <V[K]&hit_[K],T[K]>).

Module 509 chooses the first item of this list (or pairs vector) with V[K]=hit_K=1, that is to say in this example, the pair <1,5>.

Returning to FIG. 5, when the TCAM module has been selected by module 509, the counter associated with that TCAM module is decremented. Thus, module 509 provides the index of that TCAM module to an updating module 510. This updating module sends a documentation signal to a module 511 for priority list management as described with reference to FIG. 4 to decrement the count value associated with the TCAM module selected by module 507.

In reply, module 511 can indicate to module 510 that the count value has attained the value “0”. In this case, module 510 sends a shift signal to a shift module 512 in order to place the TCAM module in question (the one selected by module 509 and of which the count value has attained “0”) at the end of the list in module 508 and to shift all the rows of the list as described earlier with reference to FIG. 3B. This shift signal also indicates that the module must be invalidated by setting its validity bit to “0”. Module 512 then takes on the task of sending the necessary signals to module 508 to perform this shift and this invalidation.

In the example given above in which it has been assumed that matches are found in modules TCAM2 and TCAM5, it is furthermore assumed that it is necessary to decrement the counter of module TCAM5 since the count value has attained “0”.

Returning to FIG. 5, once the TCAM module has been selected by the selection module 509, the value it stores should be delivered.

Thus, the index of the TCAM module is supplied to a multiplexer 513 as a selection signal. Moreover the multiplexer receives as input the words 505, . . . , 506 (“hit_addr_0”, . . . , “hit_addr_N-1”) delivered by the TCAM modules 501, . . . , 502.

The multiplexer thus supplies the word corresponding to the TCAM module indicated by the selection module 509 to a reading module 514.

The reading module takes on the task of reading the value stored in the TCAM indicated by module 509 (it receives the same selection signal as module 513) and of invalidating the row of memory storing that value. The invalidation is made for example by putting the row to zero. The invalidation may also be made by putting a validity bit associated with the row to zero.

The present invention has been described and illustrated in the present detailed description with reference to the appended Figures. However the present invention is not limited to the embodiments presented. Other variants and embodiments may be deduced and implemented by the person skilled in the art on reading the present description and appended Figures.

In the claims, the term “comprise” does not exclude other elements or other steps. The indefinite article “a” does not exclude the plural. A single processor or several other units may be used to implement the invention. The different features presented and/or claimed may advantageously be combined. Their presence in the description or in different dependent claims, does not indeed exclude the possibility of combining them. The reference signs are not to be understood as limiting the scope of the invention.

1. A device for item match searching in a list, the device comprising:
a plurality of content addressable memory modules that are configured to compare in parallel an entry item with their content, said list being represented by the concatenation of the valid content of said memories in an order defined by a priority list,
a module for determining, in said priority list, the first module for which the entry item matches an item stored in said module, and
a module for reading the first item of said determined module matching the entry item.

2. A device according to claim 1, further comprising:
a module for invalidating said first item, and
an updating module for updating an item counter associated with said determined memory, said item counter representing the number of valid items stored in said memory.

3. A device according to claim 2, wherein said updating module is further configured to launch an update of said priority list when a module is empty, said update enabling said module to be placed at a lower priority level than that of the modules that are not empty.

4. A device according to claim 2, wherein, a priority index associated with said memories is updated.

5. A device according to claim 4, wherein said update comprises a shift of said module and of the following modules in the list.

6. A device according to claim 1, wherein said priority list comprises a parameter for each module, indicating whether each module is empty or not.

7. A device according to claim 6, wherein the modules are classified according to said parameter.

8. A device according to claim 1, wherein the order of the modules in said priority list reflects an allocation order.

9. A device according to claim 1, wherein said match searching is made by association of a tag of said item with a tag of an item of said list.

10. A device according to claim 1, wherein said modules are memory modules addressable by ternary content.

11. A device according to claim 1, comprising, to process a list of S×N items, N content addressable memory modules, each module being able to contain S items.

12. A device according to claim 1, comprising at least one processing module of the device formed from log₂(N) stages of multiplexers, N being the number of content addressable memory modules.

13. A method for item match searching in a list, the method comprising: p1 comparing in parallel an entry item with the content of a plurality of content addressable memory modules, said list being represented by the concatenation of the valid content of said memories in an order defined by a priority list,
determining, in said priority list, the first module for which the entry item matches an item stored in said module, and
reading the first item of said determined module matching the entry item,

14. A method according to claim 13, further comprising:
invalidating said first item, and
updating an item counter associated with said determined memory, said item counter representing the number of valid items stored in said memory.

15. A method according to claim 14, further comprising updating said priority list when a module is empty, said updating enabling said module to be placed at a lower priority level than that of the modules that are not empty.

16. A method according to claim 14, wherein a priority index associated with said memories is updated.

17. A method according to claim 16, wherein said updating comprises a shift of said module and of the following modules in the list.
